(19) United States
(12) Patent Application Publication
(10) Pub. No.: US 2026/0227469 A1
(43) Pub. Date: Aug. 6, 2026

(54) Magnetic-Field Sensing Device for Sensing Magnetic Signals Emitted from a Measurement Location

(71) Applicant: Robert Bosch GmbH, Stuttgart (DE)

(72) Inventors: Tino Fuchs, Tuebingen (DE); Janine Riedrich-Moeller, Leonberg-Warmbronn (DE); Eckhard Wehrse, Stuttgart (DE); Omar Amr Hassan Nassar, Eggenstein-Leopoldshafen (DE)

(21) Appl. No.: 19/152,961

(22) PCT Filed: Jan. 15, 2024
(86) PCT No.: PCT/EP2024/050787

§ 371 Date: Aug. 1, 2025

(30) Foreign Application Priority Data
Feb. 2, 2023 (DE) 10 2023 200 849.1

(51) Int. Cl. G01R 33/32; G01R 33/00; G01R 33/26

(52) U.S. Cl. CPC G01R 33/323; G01R 33/0005; G01R 33/0017; G01R 33/26

(57) ABSTRACT

A magnetic field detection device for sensing magnetic signals originating from a measurement location includes a magnetic field measuring unit having at least one nitrogen-vacancy center, NV-, magnetometer unit, connected to a signal processing unit. The magnetic field measurement unit is disposed on a movable manipulator unit. The magnetic field sensing device is configured to move the magnetic field measuring unit to at least two different positions relative to the measurement location by way of the movable manipulator unit and to detect a magnetic field strength and field direction at each of the at least two different positions, and to determine at least one field vector including an effective magnetic field strength and an effective field direction from the magnetic field strengths and field directions detected at the at least two different positions by way of the signal processing unit.

The present invention relates to a magnetic field sensing device for sensing magnetic signals that originate from a measurement location.

### BACKGROUND OF THE INVENTION

Optically pumped or diamond-based quantum sensors based on NV centers are particularly suitable as sensors for measuring very small magnetic field strengths. DE 10 2022 204 526.2 describes a magnetometer that utilizes optically pumped and optically detected magnetic resonance (ODMR). It is thereby exploited that, under the influence of an external magnetic field, the energy levels of certain spin states of unpaired electrons are split, the so-called Zeeman effect. The splitting of the energy levels results in changed transitions during relaxation from excited states, which can then be measured, for example, by optical excitation and frequency-dependent detection of the resulting fluorescence radiation or by observation of optical properties such as the absorption of light. From the measured optical parameters, the magnetic field strength may then in turn be inferred.

### DISCLOSURE OF THE INVENTION

According to the invention, a magnetic field sensing device for sensing magnetic signals originating from a measurement location is proposed with the features of claim 1. Advantageous configurations are the subject matter of the dependent claims and the following description.

The invention proposes to arrange a magnetic field measurement unit with at least one nitrogen-vacancy center, NV-, magnetometer unit on a movable manipulator unit and to detect a magnetic field strength and field direction, i.e., a magnetic field vector, at different positions relative to a measurement location and to determine an effective magnetic field vector from this information. The movable assembly can thus measure a plurality of different positions relative to the measurement location with only one magnetic field measurement unit, in order to thus create a three-dimensional image of the prevailing magnetic field, in particular the magnetic field originating from an object at the measurement location. The movable assembly allows for a three-dimensional reconstruction of the magnetic field-source distribution, for example of the underlying magnetic dipoles or electrical currents. A magnetic field detection device may be provided by the invention, which may be used for imaging, for example in the manner of computer tomography or magnetic resonance tomography.

In detail, a magnetic field detection device for sensing magnetic signals originating from a measurement location is now presented, which comprises a magnetic field measurement unit with at least one NV-magnetometer unit connected to a signal processing unit, wherein the magnetic field measurement unit is disposed on a movable manipulator unit. The magnetic field sensing device is configured to move the magnetic field measurement unit by means of the movable manipulator unit to at least two different positions relative to the measurement location, as well as to detect a magnetic field strength and field direction at each of the at least two different positions, and by means of the signal processing unit to determine at least one field vector comprising an effective magnetic field strength and an effective field direction from the magnetic field strengths and field directions detected at the at least two different positions. Both a wireless and wired connection are provided between the sensors and the signal processing unit.

Diamond NV magnetometers are based on reading out magnetic resonances from specific defect centers in diamond, in particular nitrogen vacancies (NV), which occur as impurities in the carbon lattice of diamond and can also be introduced in a targeted manner. If the NV center is optically excited in the ground state, e.g., by radiating in a pump laser beam having a suitable wavelength (in this case in the green wavelength range, e.g., at 532 nm for off-resonance excitation), the electrons are lifted from the triplet ground state to the excited triplet state and relax while emitting fluorescence light in the red wavelength range at 650-800 nm (637 nm=zero phonon line). Since the probability of non-spin-conserving transitions from the spin state is higher when the spin quantum number mₛ=±1, continuous excitation pumping ensures that the NV centers are largely hyperpolarized in the spin state mₛ=0.

There is an energy difference between the mₛ=0 and mₛ=±1 spin states in the ground state, which in this case is about 2.87 GHz. Thus, if microwave radiation is radiated into the diamond in addition to the optical excitation, there is a dip in the red fluorescence at this resonance frequency of 2.87 GHz, because the spin-polarized electrons are lifted by the microwave field from mₛ=0 to the mₛ=±1 ground state and excited from there by the pump light to the mₛ=±1 excited state. From there, however, primarily non-radiative transitions and weak infrared fluorescence transitions occur via the singlet state, and the fluorescence in the red range ceases.

If an external magnetic field (to be measured) is present, the so-called Zeeman effect leads to the splitting of the otherwise energetically equal mₛ=±1 triplet levels into energetically equidistant Zeeman levels. Plotting the fluorescence against a frequency spectrum of the microwave excitation then reveals two dips in the fluorescence spectrum, the frequency spacing of which is linearly proportional to the magnetic field strength of the external magnetic field. The magnetic field sensitivity is primarily defined by the minimally resolvable frequency shift and can reach 1 pT/√Hz or less. Because the nitrogen vacancy center in the single-crystal diamonds has four possible ways to position itself in the crystal lattice, the presence of an additional bias magnetic field causes the nitrogen vacancy centers present in the crystal to react differently to the external magnetic field depending on their position in the crystal. As a result, four pairs of fluorescence minima may appear in the spectrum, from the shape and position of which both the magnetic field strength as an amount and the direction of the external magnetic field are clearly determinable.

In order to make magnetic field measurements possible, the magnetic field sensing device also comprises the device for generating the bias magnetic field in the region of the sensor medium. This may be a Helmholtz coil assembly, wherein at least the sensor medium is disposed within the Helmholtz coil assembly. It may also be another device, such as a simple coil, an elongated coil, a permanent magnet solution, such as in a Hallbach array, etc. In order additionally to be able to determine vectorial (direction-dependent) magnetic information, a defined direction of the bias magnetic field is needed.

Because measurements are carried out at different positions, these positions have a different orientation to the magnetic field at the measurement location. This makes it possible to determine the position and strength of this magnetic field. Since a background field (in particular the Earth's magnetic field) is usually substantially the same at different positions (the same strength and orientation), it can be eliminated. The need for a magnetic shield is thus eliminated, however to improve the measurement results, the magnetic field detection device can also be magnetically shielded from the surrounding environment.

Another advantage of the NV sensor system is its size, especially the sensor medium. NV sensor technology has a very small active sensor volume. This capability for creating small designs also allows the sensors to be used in a geometric arrangement. In particular, very high resolution arrangements are possible due to the very small active sensor volume.

In one configuration, the magnetic field detection device is configured to determine the effective magnetic field strength and the effective field direction from a difference of the magnetic field strengths and field directions detected at the at least two different positions. This resembles a gradiometer connection of two magnetic field measurement units at different positions (gradiometry circuit), but only uses one magnetic field measurement unit, the measurement results of which are offset, and thus corresponds to computational gradiometry. Through gradiometry, i.e. substantially vector arithmetic of what is measured, the magnetic field gradient approximately corresponds to the field originating from the source, while substantially stronger background fields (which are substantially the same at both positions) are eliminated (see also above). Accordingly, the invention is particularly suitable for non-shielded measurement of weak magnetic fields. Technical details for gradiometer solutions that can also be used in the context of the present invention are disclosed in DE 102022201690.4 and are to be incorporated herein.

In one embodiment, the at least two different positions are equidistant from the measurement location or from an axis passing through the measurement location. In other words, the magnetic field measurement unit is moved around the measurement location or axis on a circular or spiral path. A spiral path is particularly suitable for large-scale objects, such as persons arranged along the axis, e.g., on a bed. This measure is on the one hand easy to implement from a technical standpoint and is known from other applications, e.g., computer tomography and can thus be adopted from it. On the other hand, it is always very easy to find two different positions that are well-suited for computational gradiometry.

In one embodiment, two different positions of the at least two different positions and the measurement location or a point on an axis passing through the measurement location are each on a straight line. In other words, the positions for two measurements relative to the measurement location are pivoted by 180° on a circular path, the center point of which is the measurement location, for example by 90° and 270°. This way, background fields can be easily eliminated.

In one configuration, the magnetic field measurement unit comprises at least two NV magnetometer units arranged in a plane. Thus, for example, a gradiometry circuit can be provided very simply. For example, a plurality of field vectors, each comprising a magnetic field strength and a field direction, can also be determined from the magnetic field strengths and field directions detected at the at least two different positions.

Further advantages and embodiments of the invention will emerge from the description and the accompanying drawings.

The invention is shown schematically in the drawings on the basis of exemplary embodiments and is described hereinafter with reference to the drawings.

### BRIEF DESCRIPTION OF THE DRAWINGS

FIG. 1 shows in a schematic block view the essential components of a magnetic field measurement device with an NV magnetometer unit as may be used in the context of the invention.

FIG. 2 shows an exemplary magnetic field measurement unit with a plurality of NV magnetometer units for use in a magnetic field detection device according to one embodiment of the invention in a schematic view.

FIG. 3 shows an exemplary magnetic field detection device according to one embodiment of the invention in a schematic view.

FIG. 4 schematically shows the measurement of magnetic signals in a magnetic field detection device according to one embodiment of the invention in a schematic view.

### EMBODIMENT(S) OF THE INVENTION

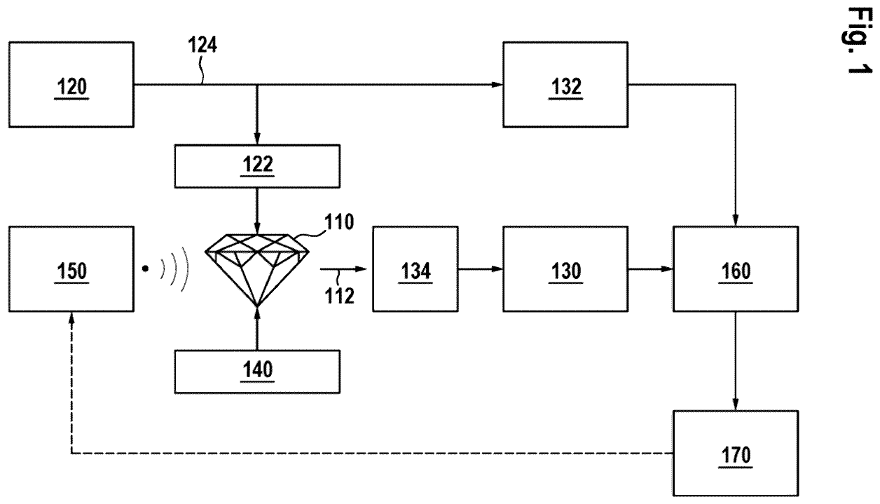

FIG. 1 schematically shows the essential components of a magnetic field measurement unit with an NV magnetometer unit according to one embodiment. First, a diamond 110 with nitrogen vacancies (NV) is present as the sensor medium. Optical excitation of the NV centers can be achieved using a suitable light source 120 such as a pump laser. Here, for example, a frequency-doubled Nd:YAG laser or semiconductor laser in the green range of about 510-532 nm, e.g. at 532 nm, is suitable for off-resonance excitation. Alternatively, LEDs in suitable wavelength ranges may also be used. Depending on the assembly, the light of the light source 120 may be radiated via suitable optical elements 122 such as mirrors, beam splitters, focusing optics such as lenses, and optionally via fiber optic elements in the diamonds 110. In addition, the excitation light may be irradiated continuously or in a pulsed manner by the laser such that, for example, time windows for interference-free fluorescence light measurement are kept clear.

Furthermore, a microwave source 150 may be present in the magnetic field measurement device capable of generating an electromagnetic field across a bandwidth that sufficiently covers the desired resonance frequency in the sensor medium, e.g., in the range of the NV centers in the diamonds 110. A microwave resonator structure may be used to homogeneously distribute the generated microwaves across the volume of the sensing range in the diamond. The resonator structure or microwave source 150 is preferably tuned for the frequency of the electron spin resonances. To enable vector magnetometry, an additional bias magnetic field is generated with a device 140. As a result, the measurement becomes intrinsically vectorial. Different spatial directions are used in the crystal structure for this purpose. For example, to generate such a magnetic field, a Helmholtz coil is suitable, in which a substantially homogeneous magnetic field can be generated in a limited range by means of a pair of coils. It can also be other equipment 140 such as a simple coil, a long coil, permanent magnet solutions such as in a Hallbach array, etc.

The resulting fluorescent light 112 from the diamond 110 may in turn be directed via suitable optical elements 134 such as optical filters, beam splitters, lenses, and/or fiber optic elements to a first photodetector 130 that is sensitive at least in the range of the fluorescence wavelength. The first photodetector 130 may also be disposed directly on the diamond 110. A second photodetector 132 is arranged to detect at least a portion of the excitation light of the light source 120, which may be decoupled by, for example, a beam splitter, a filter, or a partially permeable element. This excitation light detector signal may be used as a reference signal to eliminate background signals, for example, by modulating the excitation light by way of a lock-in amplifier, and highlighting the resonance signal of interest. Additionally, or alternatively, this reference signal may be used to account for fluctuations in excitation light. Corresponding circuitry 160, such as a pre-amplifier, log amplifier, lock-in amplifier, signal filters, or others, is thus provided to receive the signals from the first and second photodetector and to pre-process the signals in an appropriate manner for further evaluation. Finally, the pre-processed fluorescence signal may be evaluated by a signal processing unit 170, e.g., with a suitable microcontroller or processor, to obtain the desired parameters of the detected magnetic field from the signal, in particular the magnetic field strength and the direction of the magnetic field.

Of course, such a device may also comprise further units not shown, such as communication units or interfaces to output measurement results. Such a device may also be advantageously integrated into an ASIC or FPGA.

Such a magnetic field measurement unit having an NV magnetometer unit provides a variety of advantages for the present application. In addition to the very highly sensitivity already mentioned, a high measurement range (>1 Tesla) can also be covered. The underlying Zeeman effect is linearly dependent on the magnetic field present and also does not show degradation, since the measurement is based on quantum mechanical states. In addition, NV magnetometer units provide the possibility of determining external magnetic fields vectorially based on the different orientations present in the diamond lattice.

There are also alternative ways to electrically read the magnetic spin resonance in diamond. Charge carriers are detected that were lifted into the diamond conduction band by two-photon ionization of the NV centers. If such a method is used to read out the resonance effects, the parts for detecting the fluorescent light in the previous examples are not required and are replaced with suitable photo-current detectors on the diamond. However, apart from this, the method of magnetic field measurement may be transferred accordingly and may be applied in all embodiments with NV magnetometer units.

In order to be usable in an everyday environment, magnetic fields not originating from desired weak sources are to be eliminated as far as possible from the measurement, in particular the Earth's magnetic field in the range of 10⁻⁵ Tesla (several microtesla).

The elimination of the background magnetic fields may be achieved by a shield or a gradiometer assembly for the magnetic field measurement, according to exemplary embodiments. Gradiometers are generally referred to as magnetic field measurement units that are capable of detecting not only the field strength, but also the gradient of the field. For this purpose, measurement information from at least two different spatial positions can be offset against one another.

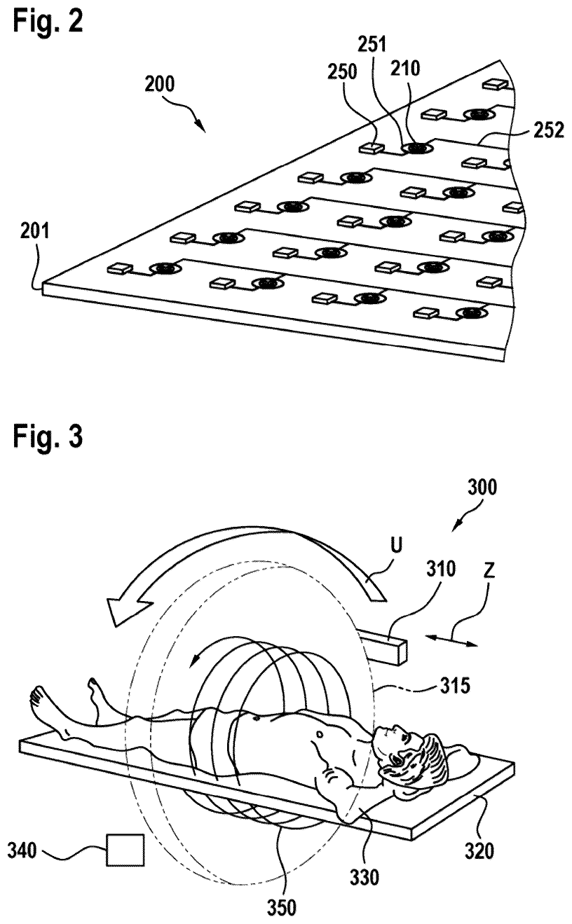

In FIG. 2, an excerpt of an exemplary magnetic field measurement unit 200 with multiple NV magnetometer units for use in a magnetic field detection device according to one embodiment of the invention is shown in a schematic view. Here, multiple NV magnetometer units are disposed in one plane in a regular two-dimensional arrangement on a substrate 201, such as a printed circuit board or PCB.

Each NV magnetometer unit comprises a sensor medium 210 in the form of a diamond crystal, each associated with a microwave resonator 251 connected via a wave guide 252 to a microwave source 250, for example in the form of an integrated circuit (IC). Further components such as, for example, an excitation light source for radiating light into the sensor media 210 and a means for generating a bias magnetic field in the area of the sensor media 210 are not shown, but may be jointly associated with all the sensor media 210. Further, a (specific) detector may be associated with each sensor medium 210, for example, as described in connection with FIG. 1.

FIG. 3 shows an exemplary magnetic field detection device 300 in a schematic view, according to one embodiment of the invention. The magnetic field detection device 300 shown comprises a bed 320 for receiving a patient 330, which in the present case represents the measurement location. Further, the magnetic field sensing device 300 comprises a magnetic field measurement unit 310 having at least one NV magnetometer unit connected to a signal processing unit 340. The signal processing unit 340 may simultaneously act as a control unit for the magnetic field sensing device 300.

The magnetic field measurement unit 310 is disposed on a movable manipulator unit 315, which in the present case is arranged to move the magnetic field measurement unit 310 in the circumferential direction U around the bed 320 and in the axial direction z along the bed 320. The manipulator unit 315 is annular in the example shown and its construction and circumferential movement in principle resemble computer tomography, however it is axially movable so that the magnetic field measurement unit 310 can be moved around the bed 320 and the patient 330 as a measurement location on a spiral path 350.

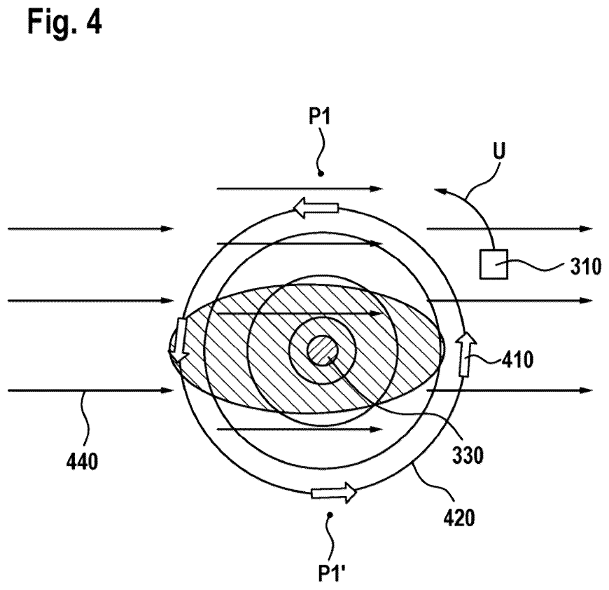

The magnetic field sensing device 300 is configured, e.g., via its control unit, to move the magnetic field measurement unit 310 to at least two different positions (e.g., P1, P1′ in FIG. 4) relative to the bed 320 and the patient 330 by way of the movable manipulator unit 315, and to detect a magnetic field strength and field direction at each of the at least two different positions. By means of the signal processing unit 340, at least one field vector comprising an effective magnetic field strength and an effective field direction can be determined from the magnetic field strengths and field directions detected at the at least two different positions.

In particular, numerous measurements may be taken on the spiral path 350. The step width of the axial movement between two measurement positions can in particular be determined depending on a resolution or image width of the magnetic field measurement unit 310 in the z direction, in particular such that after a circumnavigation the z position has increased by at most one image width. Likewise, the step width in the circumferential direction between two measurement positions can be selected as a function of a resolution or image height of the magnetic field measurement unit 310 in the circumferential direction, in particular such that after each step the U-position has increased by at most one image height. In this way, a complete three-dimensional image of the magnetic fields may be captured at the measurement location. The magnetic field measurement unit 310 may move either alone or with other detectors (e.g., x-ray detectors for CT imaging). The entire magnetic field sensing device 300 may be magnetically shielded (e.g., by wall panels) or may be unshielded.

FIG. 4 schematically shows the measurement of magnetic signals in a magnetic field detection device, for example according to FIG. 3, in a schematic view in a view to a plane in which the magnetic field measurement unit (e.g., 310) is moved. With reference to FIG. 3, this corresponds there to a cross-sectional view perpendicular to the direction, e.g., on the circle U.

A magnetic field 420 emanating from an electrical conductor with current passing through it, such as nerves, at the measurement location 330 runs circularly around the measurement location 330, wherein a field strength is illustrated by 410. Background fields (e.g., the Earth's magnetic field) are designated with 440.

For example, a measurement conducted opposite at positions P1, P1′ helps reduce the magnetic noise: If the magnetic fields are subtracted from one another from position P1 and P1′, twice the amplitude of a circular signal field results, while the ambient fields 440 with the same orientation are subtracted from each other and disappear.

1. A magnetic field sensing device for sensing magnetic signals originating from a measurement location, comprising a magnetic field measurement unit having at least one NV magnetometer unit connected to a signal processing unit, wherein:
the magnetic field measurement unit is disposed on a movable manipulator unit, and
the magnetic field sensing device is configured to move the magnetic field measurement unit to at least two different positions relative to the measurement location by way of the movable manipulator unit and to detect a magnetic field strength and field direction at each of the at least two different positions, and to determine at least one field vector comprising an effective magnetic field strength and an effective field direction from the magnetic field strengths and field directions detected at the at least two different positions using the signal processing unit.

2. The magnetic field sensing device of claim 1, wherein the magnetic field sensing device is configured to determine the effective magnetic field strength and the effective field direction from a difference between the magnetic field strengths and field directions detected at the at least two different positions.

3. The magnetic field sensing device of claim 1, wherein the at least two different positions are equidistant from the measurement location or from an axis passing through the measurement location.

4. The magnetic field sensing device of claim 1, wherein each of two different positions of the at least two different positions and the measurement location or a point are on a straight line on an axis extending through the measurement location.

5. The magnetic field sensing device of claim 1, wherein the magnetic field measurement unit comprises at least two NV magnetometer units disposed in a plane.

6. The magnetic field sensing device of claim 1, wherein the at least one NV magnetometer unit as the sensor medium comprises a diamond crystal or a portion of a diamond crystal with nitrogen vacancy centers, and wherein the magnetic field sensing device is configured to sense a magnetic field strength and field direction by reading out a spin resonance dependent on the magnetic field strength in the sensor medium.

7. The magnetic field sensing device according to claim 6, further comprising at least one excitation light source configured to radiate light into the sensor medium, at least one microwave source configured to generate a resonant field in the sensor medium, and at least one photodetector configured to sense resonance-dependent fluorescent light from the sensor medium.

8. The magnetic field sensing device of claim 7, wherein the magnetic field measurement unit comprises at least two NV magnetometer units, and wherein the at least two NV magnetometer units are associated with the same excitation light source and/or the same microwave source.

9. The magnetic field sensing device according to claim 6, further comprising at least one device configured to generate a substantially homogeneous bias magnetic field at the location of the sensor medium of the at least one NV magnetometer unit.

10. A device according to claim 1, wherein the signal processing unit is designed to determine a plurality of field vectors, each comprising a magnetic field strength and a field direction from the magnetic field strengths and field directions detected at the at least two different positions.
